(19) United States
(12) Patent Application Publication
(10) Pub. No.: US 2025/0374689 A1
(43) Pub. Date: Dec. 4, 2025

(54) IMAGE SENSOR INCLUDING DOPED REGION

(71) Applicant: SAMSUNG ELECTRONICS CO., LTD., Suwon-si (KR)

(72) Inventor: Jungwook LIM, Suwon-si (KR)

(73) Assignee: SAMSUNG ELECTRONICS CO., LTD., Suwon-si (KR)

(21) Appl. No.: 19/085,492

(22) Filed: Mar. 20, 2025

(30) Foreign Application Priority Data
May 30, 2024 (KR) 10-2024-0070908

(51) Int. Cl. H10F 39/18; H10F 39/00

(52) U.S. Cl. CPC H10F 39/1865; H10F 39/80373; H10F 39/807; H10F 39/811

(57) ABSTRACT

An image sensor includes a plurality of pixels. Each pixel of the plurality of pixels includes at least two photoelectric elements, at least two floating diffusion regions, a lateral overflow integration capacitor coupled with a floating diffusion region and configured to accumulate charges overflowed from a photoelectric element, a reset transistor coupling a floating diffusion region with a power supply voltage, a driving transistor having a gate coupled with a floating diffusion region and configured to operate based on a voltage of the floating diffusion region, a select transistor having a first terminal coupled with the driving transistor and a second terminal coupled with a column line, a deep trench isolation structure disposed between the at least two photoelectric elements, and a doped region doped with N type dopant disposed between a photoelectric element and a floating diffusion region.

### CROSS-REFERENCE TO RELATED APPLICATIONS

This application claims benefit of priority under 35 U.S.C. § 119 to Korean Patent Application No. 10-2024-0070908, filed on May 30, 2024, in the Korean Intellectual Property Office, the disclosure of which is incorporated by reference herein in its entirety.

### BACKGROUND

### 1. Field

The present disclosure relates generally to an image sensor, and more particularly, to an image sensor including a doped region disposed between a photoelectric element and a floating diffusion region.

### 2. Description of Related Art

An image sensor may refer to a device that may convert optical signals into electrical signals. Examples of an image sensor may include, but not be limited to, a chargecoupled device (CCD) image sensor, a complementary metal-oxide semiconductor (CMOS) image sensor, or the like.

In an active pixel sensor (APS), which may be a type of CMOS image sensor, when light enters a photodiode, generated charges may be transferred to a floating diffusion region. A driving transistor may convert a potential of the floating diffusion region into a voltage and may output the voltage to a column line.

Improvements in an image quality of the image sensors may be achieved by increasing a dynamic range of the image sensors.

### SUMMARY

One or more example embodiments of the present disclosure provide an image sensor for preventing photocharges from moving through an unintended path.

According to an aspect of the present disclosure, an image sensor includes a plurality of pixels. Each pixel of the plurality of pixels includes a first photoelectric element, a second photoelectric element different from the first photoelectric element, a first transfer transistor coupling the first photoelectric element with a first floating diffusion region, a second transfer transistor coupling the second photoelectric element with a second floating diffusion region, a first transistor and a second transistor each coupling the first floating diffusion region and the second floating diffusion region with a third floating diffusion region, respectively, a lateral overflow integration capacitor (LOFIC) coupled with the second floating diffusion region by a third transistor and configured to accumulate charges overflowed from the second photoelectric element, a reset transistor coupling the third floating diffusion region with a power supply voltage, a driving transistor having a gate coupled with the first floating diffusion region and configured to operate based on a voltage of the first floating diffusion region, a select transistor having a first terminal coupled with the driving transistor and a second terminal coupled with a column line, a deep trench isolation (DTI) structure between the first photoelectric element and the second photoelectric element, and a first doped region doped with N type dopants and disposed between at least one of the first photoelectric element and the first floating diffusion region or the second photoelectric element and the second floating diffusion region.

According to an aspect of the present disclosure, an image sensor includes a pixel array including a plurality of pixels and a readout circuit configured to receive a pixel signal from each pixel of the plurality of pixels. Each pixel of the plurality of pixels includes a plurality of subpixels separated from each other by a DTI structure, a plurality of floating diffusion regions, and a LOFIC configured to accumulate overflowed charges. Each subpixel of the plurality of subpixels includes a photoelectric element. A divided floating diffusion region of the plurality of floating diffusion regions is divided into a plurality of floating diffusion sub-regions disposed in respective subpixels of the plurality of subpixels, and the plurality of floating diffusion sub-regions have a same potential. A first subpixel of the plurality of subpixels includes a doped region doped with N-type dopants and is disposed between another floating diffusion region of the plurality of floating diffusion regions and the photoelectric element. The another floating diffusion region is not divided.

According to an aspect of the present disclosure, an image sensor includes a first photoelectric element having a first area and being disposed in a first region, a second photoelectric element having a second area and being disposed in a second region, a DTI structure separating the first region and the second region, a first transfer transistor coupling a first floating diffusion region with the first photoelectric element, a second transfer transistor coupling a second floating diffusion region with the second photoelectric element, a third floating diffusion region selectively electrically coupled to at least one of the first floating diffusion region or the second floating diffusion region, and a LOFIC configured to accumulate charges overflowed from the second photoelectric element. The second area is smaller than the first area. At least one of the second floating diffusion region or the third floating diffusion region is divided into divided floating diffusion regions. The divided floating diffusion regions are disposed in the first region and the second region. The divided floating diffusion regions have a same potential. A doped region is doped with N-type dopants and is disposed to be spaced apart from at least one of the first photoelectric element or the second photoelectric element, and is disposed in at least one of the first region or the second region.

Additional aspects may be set forth in part in the description which follows and, in part, may be apparent from the description, and/or may be learned by practice of the presented embodiments.

### BRIEF DESCRIPTION OF DRAWINGS

The above and other aspects, features, and advantages of certain embodiments of the present disclosure may be more apparent from the following description taken in conjunction with the accompanying drawings, in which:

FIG. 1 is a block diagram of an image sensor, according to an example embodiment;

FIG. 2 is a circuit diagram illustrating a pixel of an image sensor, according to an example embodiment;

FIGS. 3 to 5 are conceptual plan views of a pixel, according to an example embodiment;

FIG. 6 is a diagram illustrating an example of a layout of the pixel based on the circuit diagram of FIG. 2, according to an example embodiment;

FIG. 7 is a schematic plan view illustrating an example of the layout of the pixel in FIG. 6, according to an example embodiment;

FIG. 8 is a diagram illustrating a conceptual example of a cross-section taken along line A-A′ of the layout of the pixel in FIG. 7, according to an example embodiment;

FIG. 9 is a diagram illustrating an example of a cross-section taken along line A-A′ of the layout of the pixel in FIG. 7, according to an example embodiment;

FIG. 10 is a diagram illustrating an example of a cross-section taken along line B-B′ of the cross-sectional view of the pixel in FIG. 9, according to an example embodiment;

FIG. 11 is a diagram illustrating an example of the operation of a pixel according to the embodiment of FIG. 2, according to an example embodiment;

FIG. 12 is a diagram illustrating an example of a cross-section taken along line A-A′ of the layout of the pixel in FIG. 7, according to an example embodiment;

FIG. 13 is a diagram illustrating an example of the layout of the pixel based on the circuit diagram of FIG. 2, according to an example embodiment;

FIG. 14 is a plan view illustrating a schematic example of the layout of the pixel of FIG. 13, according to an example embodiment;

FIG. 15 is a diagram illustrating an example of the layout of the pixel based on the circuit diagram of FIG. 2, according to an example embodiment;

FIG. 16 is a plan view of a schematic example of the layout of the pixel of FIG. 15, according to an example embodiment;

FIG. 17 is a diagram illustrating an example of a cross-section taken along line C-C′ of the layout of the pixel in FIG. 16, according to an example embodiment;

FIG. 18 is a diagram illustrating an image sensor, according to an example embodiment;

FIG. 19 is a diagram illustrating an image sensor, according to an example embodiment; and

FIG. 20 is a diagram illustrating an electronic device, according to an example embodiment.

### DETAILED DESCRIPTION

The following description with reference to the accompanying drawings is provided to assist in a comprehensive understanding of embodiments of the present disclosure defined by the claims and their equivalents. Various specific details are included to assist in understanding, but these details are considered to be exemplary only. Therefore, those of ordinary skill in the art may recognize that various changes and modifications of the embodiments described herein may be made without departing from the scope and spirit of the disclosure. In addition, descriptions of well-known functions and structures are omitted for clarity and conciseness.

With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C,” may include any one of, or all possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” “coupled to,” “connected with,” or “connected to” another element (e.g., a second element), it means that the element may be coupled with the other element directly (e.g., wired), wirelessly, or via a third element.

The terms “first,” “second,” third” may be used to describe various elements but the elements are not limited by the terms and a “first element” may be referred to as a “second element”. Alternatively or additionally, the terms “first”, “second”, “third”, and the like may be used to distinguish components from each other and do not limit the present disclosure. For example, the terms “first”, “second”, “third”, and the like may not necessarily involve an order or a numerical meaning of any form.

As used herein, when an element or layer is referred to as “overlapping” another element or layer, the element or layer may cover and/or be disposed above at least a portion of the other element or layer, where the portion may include a fraction of the other element or may include an entirety of the other element.

Reference throughout the present disclosure to “one embodiment,” “an embodiment,” “an example embodiment,” or similar language may indicate that a particular feature, structure, or characteristic described in connection with the indicated embodiment is included in at least one embodiment of the present solution. Thus, the phrases “in one embodiment”, “in an embodiment,” “in an example embodiment,” and similar language throughout this disclosure may, but do not necessarily, all refer to the same embodiment. The embodiments described herein are example embodiments, and thus, the disclosure is not limited thereto and may be realized in various other forms.

The embodiments herein may be described and illustrated in terms of blocks, as shown in the drawings, which carry out a described function or functions. These blocks, which may be referred to herein as units or modules or the like, or by names such as device, logic, circuit, controller, counter, comparator, generator, converter, or the like, may be physically implemented by analog and/or digital circuits including one or more of a logic gate, an integrated circuit, a microprocessor, a microcontroller, a memory circuit, a passive electronic component, an active electronic component, an optical component, and the like.

In the present disclosure, the articles “a” and “an” are intended to include one or more items, and may be used interchangeably with “one or more.” Where only one item is intended, the term “one” or similar language is used. For example, the term “a processor” may refer to either a single processor or multiple processors. When a processor is described as carrying out an operation and the processor is referred to perform an additional operation, the multiple operations may be executed by either a single processor or any one or a combination of multiple processors.

As used herein, each of the terms “SiN”, “SiO”, “SiON”, and the like may refer to a material made of elements included in each of the terms and is not a chemical formula representing a stoichiometric relationship.

Hereinafter, various embodiments of the present disclosure are described with reference to the accompanying drawings.

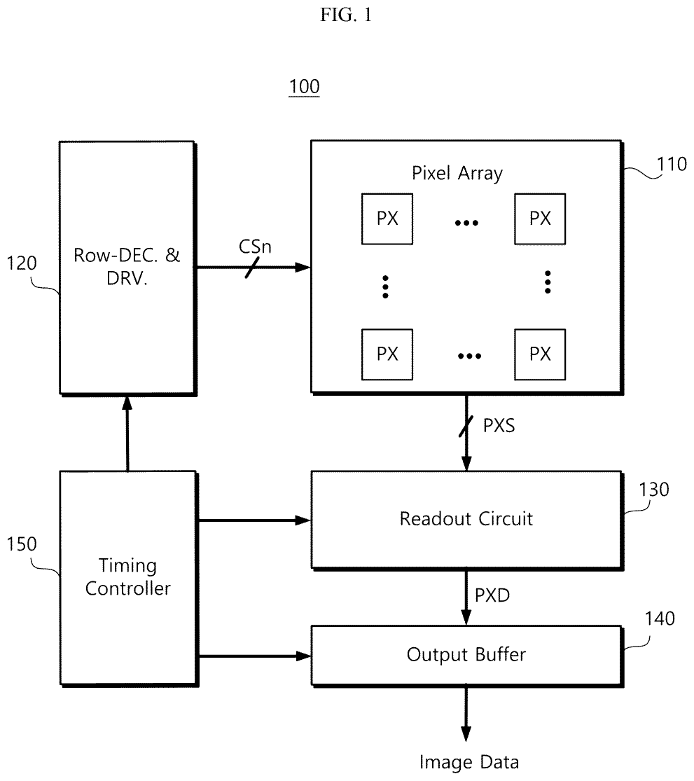

FIG. 1 is a block diagram of an image sensor, according to an example embodiment.

Referring to FIG. 1, an image sensor 100 includes a pixel array 110, a row decoder/driver 120, a readout circuit 130, an output buffer 140, and a timing controller 150.

The pixel array 110 may include a plurality of pixels PX. The plurality of pixels PX may be arranged in, for example, a matrix form. However, the present disclosure is not limited in this regard, and the plurality of pixels PX may be arranged in various forms without departing from the scope of the present disclosure. The pixel array 110 may receive, from the row decoder/driver 120, a plurality of pixel control signals CSn, such as, but not limited to, a select signal, a reset control signal, a transfer control signal, a gain control signal, a switch control signal, a voltage select signal, or the like. The pixel array 110 may operate under the control of the received pixel driving signals, and each pixel of the plurality of pixels PX may convert an optical signal into an electrical signal. An electrical signal, generated in each pixel of the plurality of pixels PX, may be provided to an analog-to-digital converter (ADC) through a plurality of column lines. For example, a pixel signal PXS generated in each pixel of the plurality of pixels PX may be provided to the ADC through a corresponding column line from among the plurality of column lines. In an example embodiment, the pixel signal PXS may include, but not be limited to, an image signal, a reset signal, or the like.

Each pixel of the plurality of pixels PX may include at least two (2) subpixels. Each of the subpixels may include a photoelectric element. For example, each pixel of the plurality of pixels PX may include two (2) subpixels, and each of the two (2) subpixels may include an additional photoelectric element.

In an example embodiment, when viewed from a direction perpendicular to a substrate, areas occupied by subpixels included in the same pixel PX may be different from each other. For example, an area of one subpixel may include a larger light-receiving area than another subpixel. As another example, a photoelectric element of one subpixel may have a larger light-receiving area than a photoelectric element of another subpixel. The photoelectric element having a relatively large light-receiving area may be referred to as a large photodiode LPD, and the photoelectric element having a relatively small light-receiving area may be referred to as a small photodiode SPD.

In an example embodiment, the photoelectric element may be and/or may include a photodiode. A photodiode may refer to a type of photoelectric element for generating charges that may be in proportion to an optical signal incident on each pixel and for accumulating the generated charges. According to example embodiments, the photoelectric element may be and/or may include, but not be limited to, at least one of a photodiode (PD), a photocapacitor, a photogate, a pinned photodiode (PPD), a partially pinned photodiode, an organic photodiode (OPD), a quantum dot photodiode (QD-PD), or combination thereof. Example embodiments are described with respect to an example in which the photoelectric element is a photodiode. Notably, the aspects presented herein may be employed with other photoelectric elements, and as such, example embodiments may not be limited to a photodiode.

In an example embodiment, each pixel of the plurality of pixels PX included in the pixel array 110 may support a dual conversion gain mode that may provide a high conversion gain (HCG) mode and/or a low conversion gain (LCG) mode. In an example embodiment, large and small photodiodes LPD and SPD may each support the dual conversion gain mode. Therefore, each pixel of the plurality of pixels PX may output a pixel signal with the high conversion gain mode and the low conversion gain mode applied to each of the large and small photodiodes LPD and SPD. Consequently, the image sensor 100 may output an image having a wide dynamic range based on the pixel signal with the high conversion gain mode and the low conversion gain mode applied to each of the large and small photodiodes LPD and SPD.

The row decoder/driver 120 may select a single row of the pixel array 110 under the control of the timing controller 150. The row decoder/driver 120 may generate a select signal to select a single row from among a plurality of rows. In addition, the row decoder/driver 120 may activate each control signal CSn for the plurality of pixels PX corresponding to the selected row in a predetermined order. Subsequently, a reset signal and an image signal generated from each pixel PX of the selected row may be provided to the readout circuit 130.

The readout circuit 130 may include an ADC. The ADC may convert a reset signal and an image signal of a pixel PX into digital signals and output the digital signals. For example, the ADC may sample the reset signal and the image signal using a correlated double sampling method and convert the sampled signals into digital signals. However, the present disclosure is not limited in this regard, and the ADC may convert the reset signal and the image signal into digital signals using various methods without departing from the scope of the present disclosure. To this end, the readout circuit 130 may further include a correlated double sampler (CDS).

The output buffer 140 may latch and output image data of each column unit provided by the readout circuit 130. The output buffer 140 may temporarily store the image data output from the readout circuit 130 under the control of the timing controller 150, and the sequentially latched image data may be output by a column decoder.

The timing controller 150 may control the pixel array 110, the row decoder/driver 120, the readout circuit 130, and the output buffer 140. The timing controller 150 may provide control signals such as, but not limited to, a clock signal and a timing control signal, for the operation of the pixel array 110, the row decoder/driver 120, the readout circuit 130, and the output buffer 140. The timing controller 150 may be and/or may include a logic control circuit, a phase-locked loop (PLL) circuit, a timing control circuit, a communication interface circuit, or the like.

In an example embodiment, subpixels included in the same pixel PX may be separated from each other by a deep trench isolation (DTI) structure. In an example embodiment, the DTI structure may be implemented as at least one of a front-side deep trench isolation (FDTI) structure, a back-side deep trench isolation (BDTI) structure, or the like.

At least one of the subpixels may include a doped region disposed between a photoelectric element and a floating diffusion node. The doped region may be doped with N-type dopants. For example, the doped region may be formed in an N-type region using ion implantation doping. In an example embodiment, the doped region may be doped at an N-doping concentration. In an example embodiment, a doping concentration of the doped region may be lower than a doping concentration of the photodiode.

In an example embodiment, the doped region may be configured to provide at least a portion of a path through which photocharges overflowed from the photodiode may move to the floating diffusion region. That is, without a path, photocharges overflowed from a photodiode of a single subpixel of a pixel PX may move through an unintended path. When a photocharge that has deviated from the path is recognized as an image signal of another subpixel, blooming may occur. Alternatively or additionally, a photocharge that has deviated from the path may not be used to generate an image signal of a subpixel in which the photocharges were generated, and as a result, signal loss may occur.

The doped region may provide a path, through which photocharges overflowed from a photodiode of a single subpixel move to an intended floating diffusion region, to prevent and/or reduce the deviation of the overflowed photocharges. As a result, the image sensor 100 with the doped region formed therein may prevent blooming and/or reduce signal loss, when compared to related image sensors.

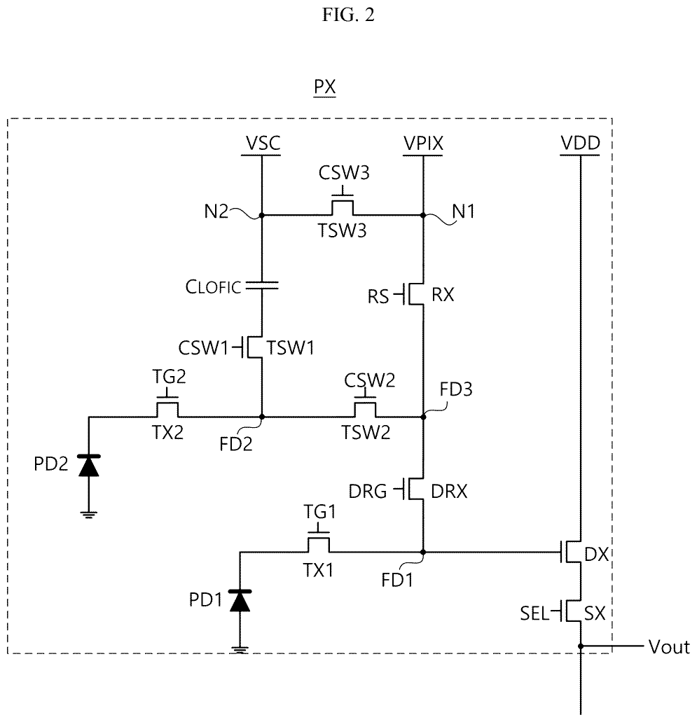

FIG. 2 is a circuit diagram illustrating a pixel of an image sensor, according to an example embodiment. The pixel PX of FIG. 2 may correspond to a pixel of the plurality of pixels PX described with reference to FIG. 1.

The pixel PX, according to an example embodiment, may include at least two (2) subpixels. Each of the subpixels may include an individual photodiode. For example, the pixel PX may include two (2) subpixels, and one of the subpixels may include a first photodiode PD1 and the other subpixel may include a second photodiode PD2. In an example embodiment, the first photodiode PD1 may be a large photodiode LPD having a relatively large light-receiving area, and the second photodiode PD2 may be a small photodiode SPD having a relatively small light-receiving area. A circuit, according to an embodiment of the pixel PX, is described with reference to FIG. 2.

Referring to FIG. 2, the pixel PX may include a plurality of photodiodes (e.g., the first photodiode PD1 and the second photodiode PD2), a plurality of transistors (e.g., a first transfer transistor TX1, a second transfer transistor TX2, a reset transistor RX, a gain control transistor DRX, a driving transistor DX, a select transistor SX, a first transistor TSW1, a second transistor TSW2, and a third transistor TSW3), and an overflow capacitor CLOFIC.

The first and second transfer transistors TX1 and TX2, may be respectively connected to the plurality of photodiodes PD1 and PD2, and may be individually turned on and/or off in response to a transfer control signal (e.g., a first transfer control signal TG1 and a second transfer control signal TG2) that may be respectively provided from the row decoder/driver 120 of FIG. 1. The first and second transfer transistors TX1 and TX2 may transfer charges accumulated in the first and second photodiodes PD1 and PD2, which may be respectively connected to the first floating diffusion region FD1 and the second floating diffusion region FD2. For example, photocharges generated in the first photodiode PD1 may be moved to the first floating diffusion region FD1 by the turned-on first transfer transistor TX1. As another example, photocharges generated in the second photodiode PD2 may be moved to the second floating diffusion region FD2 by the turned-on second transfer transistor TX2.

The plurality of floating diffusion regions (e.g., the first floating diffusion region FD1, the second floating diffusion region FD2, and a third floating diffusion region FD3) may be disposed to be separated from each other by at least one transistor. In an example embodiment, the second floating diffusion region FD2 and the third floating diffusion region FD3 may be disposed to be separated from each other by the second transistor TSW2. The first floating diffusion region FD1 and the third floating diffusion region FD3 may be disposed to be separated from each other by the gain control transistor DRX. At least a portion of the plurality of floating diffusion regions FD1 to FD3 may be electrically coupled to each other and/or may be separated from each other during a readout operation.

In an example embodiment, the overflow capacitor CLOFIC may be and/or may include a lateral overflow integration capacitor (LOFIC). In an example embodiment, one end of the overflow capacitor CLOFIC may be connected to the second floating diffusion region FD2 through the first transistor TSW1. Alternatively, in an example embodiment, one end of the overflow capacitor CLOFIC may be directly connected to the second floating diffusion region FD2. The other end of the overflow capacitor CLOFIC may be connected to a voltage node VSC. Charges overflowed from the second photodiode PD2 may be accumulated in the overflow capacitor CLOFIC via the second floating diffusion region FD2.

The overflow capacitor CLOFIC may be connected to the second floating diffusion region FD2 through the first transistor TSW1. The first transistor TSW1 may be turned on and/or off during a readout operation of the second photodiode PD2 in response to the first control signal CSW1 provided from the row decoder/driver 120 of FIG. 1. For example, the first transistor TSW1 may be turned on in low conversion gain (LCG) mode of the second photodiode PD2 to electrically couple capacitance of the overflow capacitor CLOFIC to the first floating diffusion region FD1 together with the second floating diffusion region FD2 and the third floating diffusion region FD3.

The first floating diffusion region FD1 may be connected to the third floating diffusion region FD3 through the gain control transistor DRX. The gain control transistor DRX may be turned on and/or off in response to a gain control signal DRG provided from the row decoder/driver 120 of FIG. 1. For example, the gain control transistor DRX may be turned on in low conversion gain (LCG) mode of the first photodiode PD1 to electrically couple capacitance of the third floating diffusion region FD3 to the first floating diffusion region FD1. The gain control transistor DRX may be turned off in high conversion gain (HCG) mode of the first photodiode PD1 to electrically separate the third floating diffusion region FD3 from the first floating diffusion region FD1.

The first floating diffusion region FD1 may be connected to the third floating diffusion region FD3 through the gain control transistor DRX. The first floating diffusion region FD1 may be connected to a gate of the driving transistor DX operating as a source follower amplifier.

The driving transistor DX may have one end connected to a power supply voltage node VDD, and the other end may be connected to the select transistor SX. The driving transistor DX may have a gate connected to the first floating diffusion region FD1 and may provide functions of a source follower amplifier. For example, the driving transistor DX may convert a potential of the first floating diffusion region FD1 into a voltage. The driving transistor DX may output an output signal Vout, as a pixel signal, to a column line CLi via the select transistor SX. Alternatively or additionally, the driving transistor DX may output an output signal Vout converted from the potential of the first floating diffusion region FD1 in which the first floating diffusion region FD1 and/or the second floating diffusion region FD2 is electrically coupled to the column line CLi.

The select transistor SX may be turned on when selecting a pixel PX to be read out. The select transistor SX may be driven by a select signal SEL. In an example embodiment, the select signal SEL may be provided for each row. When the select transistor SX is turned on, a voltage amplified through the driving transistor DX may be transmitted to a drain of the select transistor SX. The select transistor SX may output the received voltage to the column line CLi.

In an example embodiment, the reset transistor RX may have one end connected to the third floating diffusion region FD3, and the other end may be connected to a pixel voltage node VPIX through a first node N1. The overflow capacitor CLOFIC may have one end connected to a voltage node VSC through a second node N2. In an example embodiment, the magnitude of a voltage provided through the pixel voltage node VPIX may be the same as or different from the magnitude of a voltage provided through the voltage node VSC. Alternatively or additionally, at least one of the magnitude of the voltage provided through the pixel voltage node VPIX and/or the magnitude of the voltage provided through the voltage node VSC may be the same as or different from the magnitude of a voltage provided from the power supply voltage VDD.

The first node N1 and the second node N2 may be connected to each other through a third transistor TSW3. The third transistor TSW3 may be turned on during an operation of reading a reset signal of the second photodiode PD2 in low conversion gain (LCG) mode.

The reset transistor RX may reset at least one of the plurality of floating diffusion regions FD1 to FD3 in response to a reset control signal RS. For example, the reset transistor RX may have a source connected to the third floating diffusion region FD3, as illustrated in FIG. 2. When the reset control signal RS is activated while the reset control signal RS and the gain control signal DRG are activated, the gain control transistor DRX may be turned on and a reset voltage may be provided from the first node N1 to the first floating diffusion region FD1. Alternatively or additionally, when the reset control signal RS and a second control signal CSW2 are activated, a reset voltage may be provided from the first node N1 to the second and third floating diffusion regions FD2 and FD3. During the readout operation, the gain control transistor DRX and the second transistor TSW2 may be simultaneously turned on, or only one transistor may be turned on, or both transistors may be turned off.

According to an example embodiment, subpixels of a pixel PX may be separated from each other by a DTI structure. Regions separated by the DTI structure in the pixel PX may include a first region and a second region. One of the subpixels may be disposed in the first region, and another subpixel may be disposed in the second region. The first region and the second region may be separated from each other by the DTI structure.

In an example embodiment, the second floating diffusion region FD2 may include a 2-1-th floating diffusion region and a 2-2-th floating diffusion region with the DTI structure interposed therebetween. For example, the 2-1-th floating diffusion region may be disposed in the first region, and the 2-2-th floating diffusion region may be disposed in the second region. The 2-1-th floating diffusion region and the 2-2-th floating diffusion region may be electrically connected to each other and have the same potential.

In an example embodiment, the third floating diffusion region FD3 may include a 3-1-th floating diffusion region and a 3-2-th floating diffusion region with the DTI structure interposed therebetween. For example, the 3-1-th floating diffusion region may be disposed in the first region, and the 3-2-th floating diffusion region may be disposed in the second region. The 3-1-th floating diffusion region and the 3-2-th floating diffusion region may be electrically connected to each other and have the same potential.

The pixel PX may include at least one doped region. For example, the doped region may be disposed between either the first photodiode PD1 and the first floating diffusion region FD1, or the second photodiode PD2 and the second floating diffusion region FD2.

In an example embodiment, when the doped region is disposed between the first photodiode PD1 and the first floating diffusion region FD1, photocharges overflowed from the first photodiode PD1 may move to the first floating diffusion region FD1 via the doped region. Therefore, when the second floating diffusion region FD2 includes a 2-1-th floating diffusion region disposed in the first region and a 2-2-th floating diffusion region disposed in the second region, photocharges overflowed from the first photodiode PD1 may not move to the 2-1-th floating diffusion region but may move to the first floating diffusion region FD1 via the doped region. Accordingly, blooming and a decrease in image signal based on the first photodiode PD1 may be prevented and/or reduced, when compared to a related image sensor.

In an example embodiment, when the doped region is disposed between the second photodiode PD2 and the second floating diffusion region FD2, photocharges overflowed from the second photodiode PD2 may move to the second floating diffusion region FD2 via the doped region. Therefore, when the third floating diffusion region FD3 includes a 3-1-th floating diffusion region disposed in the first region and a 3-2-th floating diffusion region disposed in the second region, photocharges overflowed from the second photodiode PD2 may not move to the 3-2-th floating diffusion region but may move to the second floating diffusion region FD2 via the doped region. Accordingly, blooming and a decrease in image signal based on the second photodiode PD2 may be prevented and/or reduced, when compared to a related image sensor.

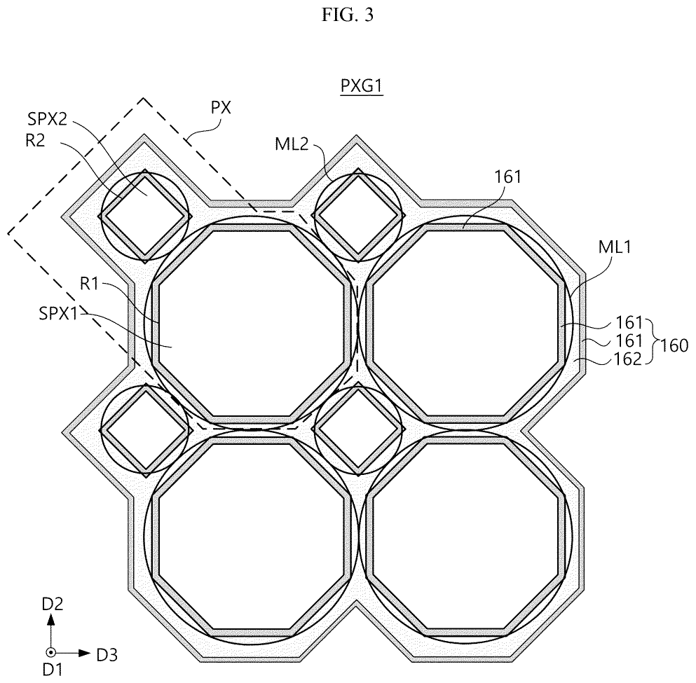

FIGS. 3 to 5 are conceptual plan views of a pixel of an image sensor, according to example embodiments. For example, FIGS. 3 to 5 are plan views as viewed from a first direction D1, which is perpendicular to a plane of a substrate.

Pixels PX of FIGS. 3 to 5 may include and/or may be similar in many respects to the pixel PX described above with reference to FIGS. 1 and 2, and may include additional features not mentioned above. Consequently, repeated descriptions of the pixels PX of FIGS. 3 to 5 described above with reference to FIGS. 1 and 2 may be omitted for the sake of brevity.

Pixels PX of FIGS. 3 to 5 may be pixels PX corresponding to a portion of a pixel array 110 of an image sensor 100. For example, each of FIGS. 3 to 5 illustrates an example of four (4) pixels PX.

According to an example embodiment, among the pixels PX, every predetermined number of pixels may form a pixel group PXG. FIGS. 3 to 5 illustrate pixel groups PXG1, PXG2, and PXG3, respectively, each group including four (4) pixels. However, the present disclosure is not limited in this regard, and each pixel group may include fewer or more than four (4) pixels PX.

In an example embodiment, each pixel PX of the pixel groups PXG1, PXG2, and PXG3 may include a plurality of subpixels. For example, each pixel PX of the pixel groups PXG1, PXG2, and PXG3 of FIGS. 3 to 5 may include two (2) subpixels (e.g., a first subpixel SPX1 and a second subpixel SPX2). In an example embodiment, the first subpixel SPX1 may include a large photodiode LPD, and the second subpixel SPX2 may include a small photodiode SPD. However, the present disclosure is not limited in this regard, and the first subpixel SPX1 may include the small photodiode SPD and the second subpixel SPX2 may include the large photodiode LPD.

In an example embodiment, pixels of a pixel group may share at least one subpixel. For example, the pixel group may include a plurality of first subpixels and a single second subpixel shared by the plurality of first subpixels. Each of the first subpixels may include a large photodiode LPD, and the second subpixel may include a small photodiode SPD.

FIGS. 3 to 5 illustrate examples in which each of the pixel groups PXG1, PXG2, and PXG3 includes four (4) pixels PX, and each of the four (4) pixels PX includes two (2) subpixels SPX1 and SPX2.

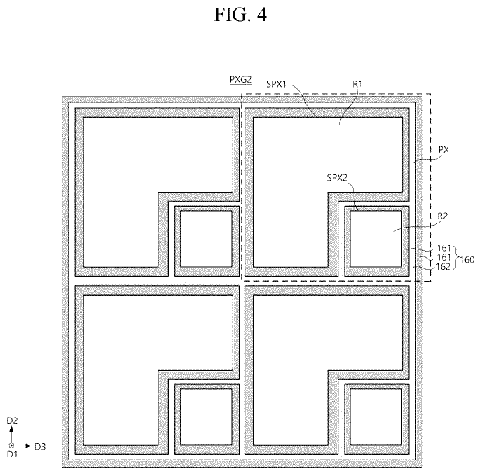

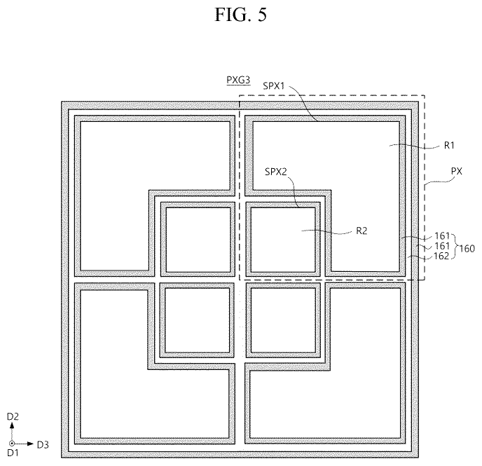

Referring to FIGS. 3 to 5, the first subpixel SPX1 may be disposed in a first region R1, and the second subpixel SPX2 may be disposed in a second region R2. Referring to FIG. 3, the first subpixel SPX1 may include a first microlens ML1, and the second subpixel SPX2 may include a second microlens ML2. Although not illustrated in FIGS. 4 and 5, each subpixel of the pixel groups PXG2 and PXG3 may also include an individual microlens.

Referring to FIGS. 3 to 5, the subpixels SPX1 and SPX2 of the pixel PX may be separated by a separation structure. In an example embodiment, the first region and the second region may be separated from each other by a DTI structure. In an example embodiment, the first region and the second region may include at least a portion of a separation structure separating the subpixels SPX1 and SPX2. In an example embodiment, the separation structure may include a DTI structure.

Referring to FIGS. 3 to 5, the pixel PX may include a separation structure 160 disposed between the subpixels SPX1 and SPX2.

Referring to FIGS. 3 to 5, in an example embodiment, the separation structure 160 may include a conductive layer 161 and a separation insulating layer 162. The conductive layer 161 may include a conductive material such as, but not limited to, a polysilicon or a metal. The separation insulating layer 162 may include, but not be limited to, a silicon oxide (SiO), a silicon nitride (SiN), a metal oxide, or combinations thereof.

Referring to FIGS. 3 to 5, in an example embodiment, at least a portion of the separation structure of one pixel PX may be connected to at least a portion of the separation structure of another pixel PX. For example, the conductive layer of the separation structure of one pixel PX may be extended, and the extended conductive layer may form the conductive layer of the separation structure of another pixel PX.

Referring to FIGS. 3 to 5, in an example embodiment, each of the pixel groups PXG1, PXG2, and PXG3 may include a separation structure separating each of the pixel groups PXG1, PXG2, and PXG3 from another pixel group.

In an example embodiment, the separation structure may be formed to separate a subpixel from another subpixel.

Referring to FIGS. 3 to 5, components of a pixel PX, according to an example embodiment, may be divided and disposed in subpixels. For example, a portion of the components of the pixel PX described with reference to FIG. 2 may be disposed in the first subpixel SPX1, and others components may be disposed in the second subpixel SPX2. In an example embodiment, a single component may be divided and disposed in both of the subpixels SPX1 and SPX2. In an example embodiment, at least one of a plurality of floating diffusion nodes FD1 to FD3 may be divided and disposed in both of the subpixel SPX1 and SPX2. For example, the second floating diffusion region FD2 of FIG. 2 may be divided into a 2-1-th floating diffusion region, disposed in the first region, and a 2-2-th floating diffusion region disposed in the second region. The 2-1-th floating diffusion region and the 2-2-th floating diffusion region may be electrically connected to each other and may have the same potential. Alternatively or additionally, the third floating diffusion region FD3 may be divided into a 3-1-th floating diffusion region, disposed in the first region, and a 3-2-th floating diffusion region disposed in the second region. The 3-1-th floating diffusion region and the 3-2-th floating diffusion region may be electrically connected to each other and may have the same potential.

Referring to FIG. 3, in an example embodiment, when viewed from a first direction D1, a first subpixel SPX1 may be disposed in a first region R1 having an octagonal shape and a second subpixel SPX2 may be disposed in a second region R2 having a rectangular shape.

Referring to FIG. 4, in an example embodiment, when viewed from a first direction D1, a first subpixel SPX1 may be disposed in a first region R1 having a rotated L shape and the second subpixel SPX2 may be disposed in a second region R2 having a rectangular shape. The second subpixel SPX2 may be disposed adjacent to a concave shape of the first subpixel SPX1. The concave shapes of the first subpixels SPX1 of each of the pixel groups PXG1, PXG2, and PXG3 may face the same direction.

Referring to FIG. 5, in an example embodiment, when viewed from a first direction D1, a first subpixel SPX1 may be disposed in a first region R1 having a rotated L shape and a second subpixel SPX2 may be disposed in a second region R2 having a rectangular shape. The second subpixel SPX2 may be disposed adjacent to a concave shape of the first subpixel SPX1. The concave shapes of the first subpixels SPX1 of each of the pixel groups PXG1, PXG2, and PXG3 may be disposed adjacent to each other.

The shapes of the first region R1 and the second region R2 are not limited to the shapes illustrated in FIGS. 3 to 5. For example, each of the first region R1 and the second region R2 may have a circular or rectangular shape.

Referring to FIGS. 3 to 5, pixels PX of each of pixel group PXG1, PXG2, and PXG3 may include color filters of a Bayer pattern. For example, among pixels of each of the pixel groups PXG1, PXG2, and PXG3, pixels PX following a diagonal may include a green color filter, and the remaining two (2) pixels PX may include a red color filter and a blue color filter, respectively.

Referring to FIGS. 3 to 5, pixels PX of each of the pixel groups PXG1, PXG2, and PXG3 may include the same color filter. For example, the pixel array 110 of FIG. 1 may have a tetra-cell structure, and four (4) pixels having the same color filter may form a pixel group. Two pixel groups disposed in diagonal direction may include a green color filter and, among the remaining pixel groups disposed in a diagonal direction, one pixel group may include a red color filter and another pixel group may include a blue color filter. For example, the pixel groups may be disposed in a Bayer pattern.

However, the present disclosure is not limited in this regard, and each pixel PX and/or each pixel group may include a color filter corresponding to a color pattern other than the Bayer pattern, and the color pattern of each pixel PX or each pixel group is not limited to the Bayer pattern.

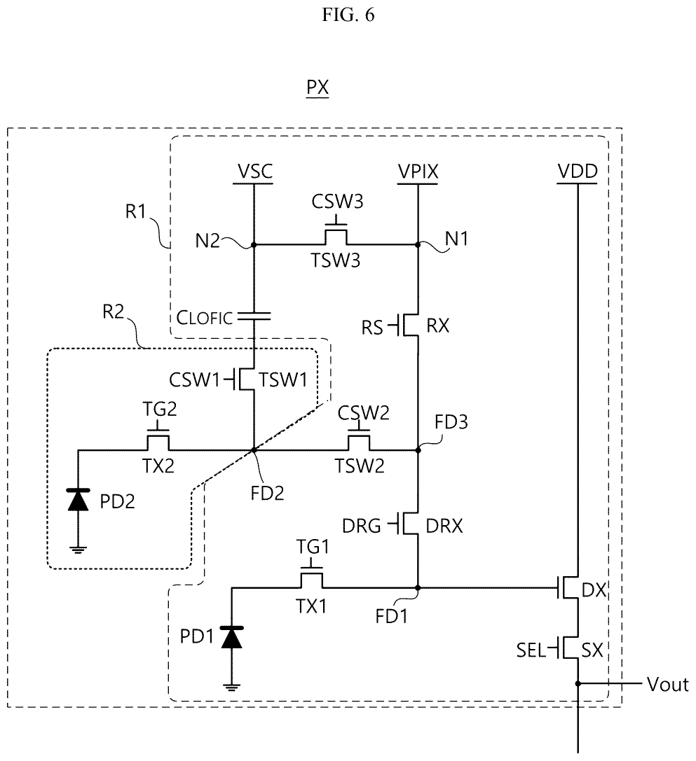

FIG. 6 is a diagram illustrating an example of a pixel layout based on the circuit diagram of the pixel in FIG. 2. The circuit diagram of a pixel PX depicted in FIG. 6 is similar in many respects to the circuit diagram of the pixel PX described above with reference to FIG. 2, and may include additional features not mentioned above. Consequently, repeated descriptions of the circuit diagram of FIG. 6 described above with reference to FIG. 2 may be omitted for the sake of brevity.

Referring to FIG. 6, the pixel PX, according to an example embodiment, may include a second photodiode PD2, a second transfer transistor TX2, a first transistor TSW1, and a second floating diffusion region FD2 disposed in the second region R2. Other components of the pixel PX and the second floating diffusion region FD2 may be disposed in the first region R1. For example, among the components of the pixel PX, the first photodiode PD1 and the first transfer transistor TX1 may be disposed in the first region R1, and the second photodiode PD2 and the second transfer transistor TX2 may be disposed in the second region R2. Alternatively or additionally, the second floating diffusion region FD2 may be divided and disposed in both the first region R1 and the second region R2. Components other than the first photodiode PD1, the first transfer transistor TX1, the second photodiode PD2, the second transfer transistor TX2, and the second floating diffusion region FD2 may be disposed in either one of the first region R1 and the second region R2. The first region R1 and the second region R2 may be regions disposed in different locations when viewed from a direction, perpendicular to the plane of the substrate.

In an example embodiment, the overflow capacitor CLOFIC may be disposed in either one of the first region R1 or the second region R2, or may be disposed outside the regions. In an example embodiment, the overflow capacitor CLOFIC may be configured as an in-pixel capacitor or as a capacitor outside the pixel.

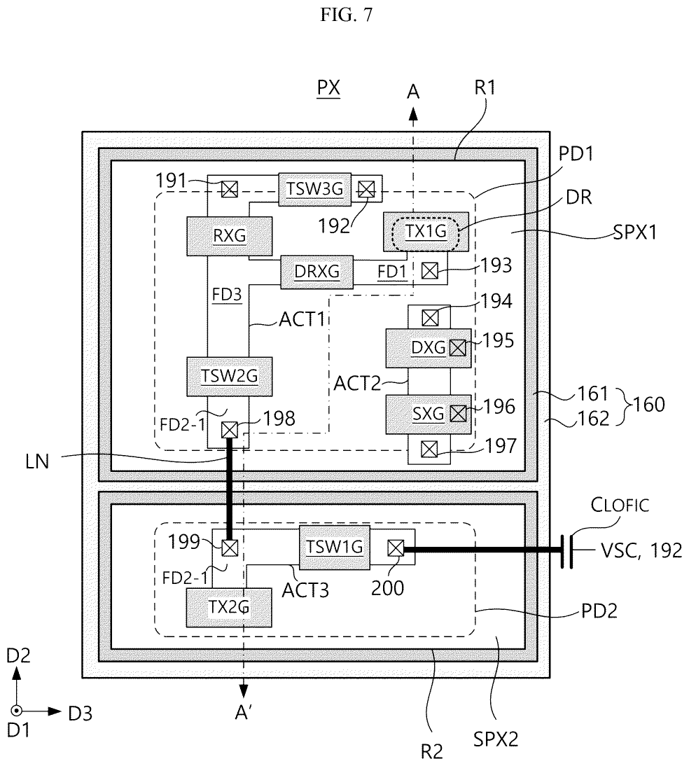

FIG. 7 is a schematic plan view illustrating an example of the layout of the pixel in FIG. 6, according to an example embodiment. The plan view may be a plan view when viewed from a first direction D1, which is perpendicular to the substrate. A pixel PX of FIG. 7 may include and/or may be similar in many respects to the pixel PX described above with reference to FIGS. 1 to 6, and may include additional features not mentioned above. Consequently, repeated descriptions of the pixel PX of FIG. 7 described above with reference to FIGS. 1 to 6 may be omitted for the sake of brevity.

Referring to FIG. 7, in an example embodiment, a first subpixel SPX1 may be disposed in the first region R1, and a second subpixel SPX2 may be disposed in the second region R2. The first subpixel SPX1 disposed in the first region may include a first photodiode PD1, a gate terminal TX1G of a first transfer transistor, a doped region DR, a gate terminal DXG of a driving transistor, a gate terminal SXG of a select transistor, a gate terminal RXG of a reset transistor, a gate terminal TSW2G of a second transistor, a gate terminal TSW3G of a third transistor, a first floating diffusion region FD1, and a third floating diffusion region FD3. The second subpixel SPX2 disposed in the second region may include a second photodiode PD2, a gate terminal TX2G of a second transfer transistor, and a gate terminal TSW1G of a first transistor.

In an example embodiment, the gate terminal TX1G of the first transistor, the gate terminal RXG of the reset transistor, the gate terminal TSW2G of the second transistor, the gate terminal TSW3G of the third transistor, the first floating diffusion region FD1, and the third floating diffusion region FD3 may be disposed in a first active region ACT1 of the first subpixel SPX1. The gate terminal DXG of the driving transistor and the gate terminal SXG of the select transistor may be disposed in a second active region ACT2. However, the present disclosure is not limited in this regard, and active regions may be formed in a different number, and components may be disposed differently from the above description without departing from the scope of the present disclosure.

In an example embodiment, a first contact 191 may be connected to a pixel voltage node VPIX of FIG. 6, and a second contact 192 may be connected to a voltage node VSC and one end of an overflow capacitor CLOFIC. A third contact 193 may be connected to a fifth contact 195. A fourth contact 194 may be connected to a power supply voltage node VDD, a sixth contact 196 may receive a select signal SEL, and a seventh contact 197 may be connected to a column line. An eighth contact 198 may be connected to a ninth contact 199, and a tenth contact 200 may be connected to the other end of the overflow capacitor CLOFIC.

A second floating diffusion region FD2 of the pixel PX, according to an example embodiment, may be divided into a plurality of regions. The second floating diffusion region FD2 divided into a plurality of regions may be disposed in both the first region R1 and the second region R2. For example, the second floating diffusion region FD2 may be divided into a 2-1-th floating diffusion region FD2-1 and a 2-2-th floating diffusion region FD2-2. The 2-1-th floating diffusion region FD2-1 and the 2-2-th floating diffusion region FD2-2 may be electrically connected to each other through an interconnection LN and may have the same potential.

The first region R1 and the second region R2 may be separated by a separation structure 160. In an example embodiment, the separation structure 160 may be and/or may include a DTI structure, and may include a conductive layer 161 and a separation insulating layer 162.

The layout described in FIG. 7 is only an example, and some components illustrated in FIG. 7 may be disposed in another sub-pixel. For example, the gate terminal TSW3G of the third transistor may be disposed in the second sub-pixel SPX2.

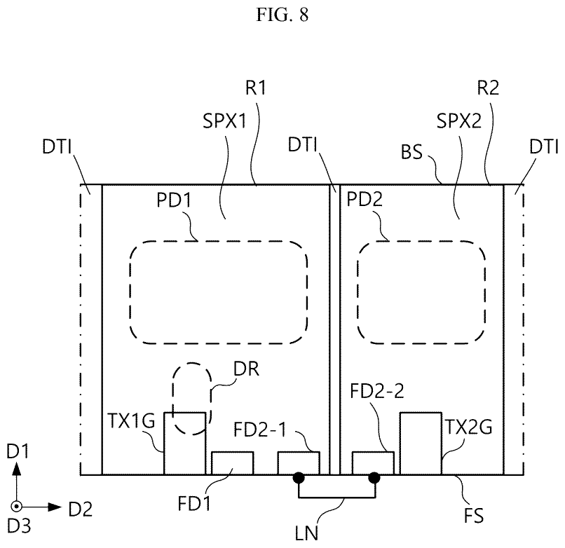

FIG. 8 is a diagram illustrating a conceptual example of a cross-section taken along line A-A′ of the layout of the pixel PX in FIG. 7, according to an example embodiment.

Referring to FIG. 8, the pixel PX may include the first subpixel SPX1, disposed in the first region R1, and the second subpixel SPX2 disposed in the second region R2.

In an example embodiment, the first subpixel SPX1 and the second subpixel SPX2 may include a first photodiode PD1 and a second photodiode PD2 within a substrate having a first surface FS and a second surface BS, respectively. The first photodiode PD1 and the second photodiode PD2 may be and/or may include an N-type doped region within the substrate.

In an example embodiment, the first subpixel SPX1 and the second subpixel SPX2 may respectively include first and second gate nodes TX1G and TX2G of a transfer transistor having at a portion extending in a first direction D1, which is an internal direction perpendicular to a plane of the substrate. The first and second gate nodes TX1G and TX2G may be and/or may include vertical gates. The first subpixel SPX1 may include a first floating diffusion region FD1.

In an example embodiment, the first subpixel SPX1 and the second subpixel SPX2 may be separated from each other by a DTI structure DTI.

The second floating diffusion region FD2 of the pixel PX, according to an example embodiment, may be divided and disposed in both the first subpixel SPX1 and the second subpixel SPX2 separated by the DTI structure DTI. For example, the second floating diffusion region FD2 may include a 2-1-th floating diffusion region FD2-1, disposed in the first subpixel SPX1, and a 2-2-th floating diffusion region FD2-2 disposed in the second subpixel SPX2. The 2-1-th floating diffusion region FD2-1 and the 2-2-th floating diffusion region FD2-2 may be electrically connected to each other through an interconnection LN and have the same potential.

The first subpixel SPX1 of the pixel PX, according to an example embodiment, may include a doped region DR doped with N-type dopants. The doped region DR may be disposed at a predetermined depth from the first surface FS in a first direction D1, perpendicular to the first surface FS. The doped region DR may be disposed between the first photodiode PD1 and the first floating diffusion region FD1 disposed in the first subpixel SPX1. For example, a center of the doped region DR may be disposed closer to the first surface FS in the first direction D1 perpendicular to the first surface FS than a center of the first photodiode PD1, and may be disposed farther from the first surface FS in the first direction D1 perpendicular to the first surface FS than a center of the first floating diffusion region FD1.

In an example embodiment, at least a portion of the doped region DR may be disposed to overlap the gate terminal TX1G of the first transfer transistor. For example, referring to FIG. 8, when viewed from the first direction D1 perpendicular to the first surface FS, the doped region DR may overlap the gate terminal TX1G of the first transfer transistor.

In an example embodiment, when viewed from the first direction D1, a portion of the doped region DR may overlap the gate terminal TX1G of the first transfer transistor and may not overlap the first floating diffusion region FD1.

In an example embodiment, when viewed from the first direction D1, a portion of the doped region DR may overlap the gate terminal TX1G of the first transfer transistor, and another portion of the doped region DR may overlap the first floating diffusion region FD1.

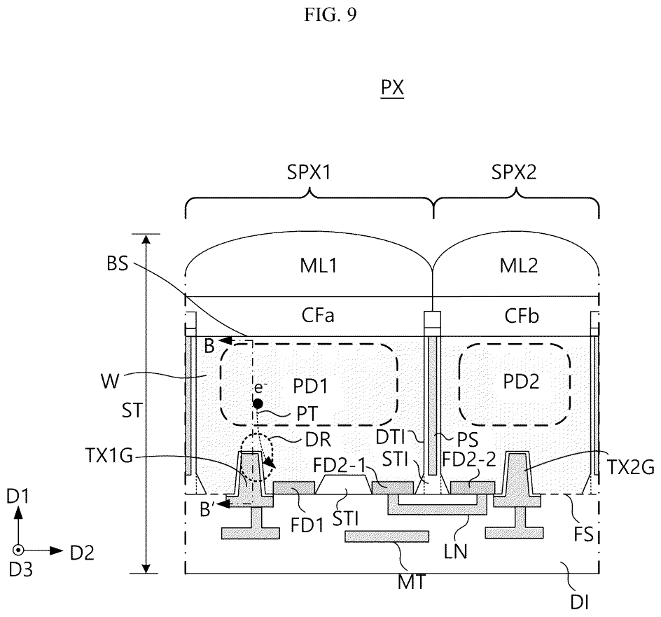

FIG. 9 is a diagram illustrating an example of a cross-section taken along line A-A′ of the layout of the pixel in FIG. 7, according to an example embodiment. The cross-section of a pixel PX depicted in FIG. 9 is similar in many respects to the cross-section of the pixel PX described above with reference to FIG. 8, and may include additional features not mentioned above. Furthermore, the pixel PX of FIG. 9 may include and/or may be similar in many respects to the pixel PX described above with reference to FIGS. 1 to 8, and may include additional features not mentioned above. Consequently, repeated descriptions of the cross-section of the pixel PX of FIG. 9 described above with reference to FIGS. 1 to 8 may be omitted for the sake of brevity.

Referring to FIG. 9, the pixel PX may include a structure ST and an insulating layer DI. The structure ST may include a substrate W having a first surface FS and a second surface BS. The insulating layer DI may include a metal layer MT for transmitting electrical signals.

The pixel PX may include a first subpixel SPX1 and a second subpixel SPX2.

The first subpixel SPX1 and the second subpixel SPX2 may include first and second microlenses ML1 and ML2 and first and second color filters CFa and CFb, respectively. The first and second color filters CFa and CFb may be color filters of the same color or different colors.

The first subpixel SPX1 and the second subpixel SPX2 may be separated by a separation structure. In an example embodiment, the separation structure may include a DTI structure DTI and a shallow trench isolation structure STI. For example, the DTI structure DTI may include an FDTI structure. The DTI structure DTI may include a conductive layer PS therein. The conductive layer PS may include a conductive material such as, but not limited to, a polysilicon or a metal. A separation insulating layer, which may be filled with silicon oxide (SiO), silicon nitride (SiN), metal oxide, or combinations thereof, may be provided between an internal surface of the DTI structure DTI and the conductive layer PS. One end of the DTI structure DTI may be connected to the shallow trench isolation structure STI. In an example embodiment, the shallow trench isolation structure STI may include a shallow trench isolation.

The shallow trench isolation structure STI may be formed in the substrate W to define an active region. The shallow trench isolation structure STI may fill a shallow trench recessed into the substrate W from the first surface FS of the substrate W. Consequently, the shallow trench isolation structure STI may be disposed adjacent to the first surface FS of the substrate W. The shallow trench isolation structure STI may be exposed by the first surface FS. A portion of the shallow trench isolation structure STI may vertically overlap a portion of the DTI structure DTI. The shallow trench isolation structure STI may be connected to the DTI structure DTI.

The shallow trench isolation structure STI may include at least one of various insulating materials. For example, the shallow trench isolation structure STI may include, but not be limited to, at least one of a silicon oxide (SiO), a silicon nitride (SiN), or a silicon oxynitride (SiON).

The first subpixel SPX1 of the pixel PX, according to an example embodiment, may include a doped region DR doped with N-type dopants. The doped region DR may be disposed farther from the first surface FS than the first floating diffusion region FD1. The doped region DR may be disposed closer to the first surface FS than the first photodiode PD1. The doped region DR may be disposed at a predetermined distance from each of the first photodiode PD1 and the first floating diffusion region FD1. The doped region DR may be disposed between the first photodiode PD1 and the first floating diffusion region FD1. Photocharges e− overflowed from the first photodiode PD1 may move to the first floating diffusion region FD1 through the doped region DR along a virtual path PT. Accordingly, the photocharges e− overflowed from the first photodiode PD1 may not escape to the 2-1-th floating diffusion region FD2-1. As a result, blooming and signal loss of the first subpixel SPX1 may be prevented.

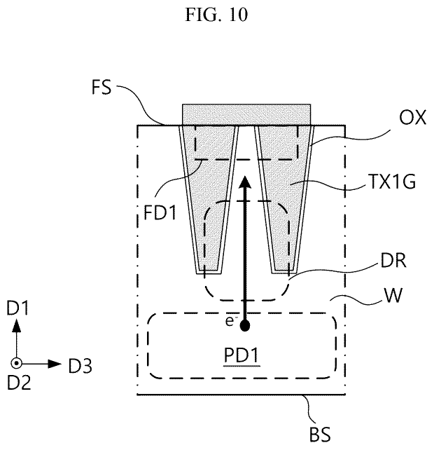

FIG. 10 is a diagram illustrating an example of a cross-section taken along line B-B′ of the cross-sectional view of the pixel in FIG. 9. The cross-section of a pixel PX depicted in FIG. 10 is similar in many respects to the cross-sections of the pixel PX described above with reference to FIGS. 8 and 9, and may include additional features not mentioned above. Furthermore, the pixel PX of FIG. 10 may include and/or may be similar in many respects to the pixel PX described above with reference to FIGS. 1 to 9, and may include additional features not mentioned above. Consequently, repeated descriptions of the cross-section of the pixel PX of FIG. 10 described above with reference to FIGS. 1 to 9 may be omitted for the sake of brevity.

The gate terminal TX1G of the first transfer transistor, according to an example embodiment, may be and/or may include a dual gate terminal. When viewed from the second direction D2, a portion of a doped region DR may be disposed between a plurality of protrusions in a first direction of the dual gate terminal. A portion of the doped region DR may be disposed closer to a second surface BS of a substrate W than the plurality of protrusions. The first floating diffusion region FD1 may be disposed closer to a first surface FS than the doped region DR.

In an example embodiment, when viewed from a second direction D2, the doped region DR may not overlap the first floating diffusion region FD1.

Photocharges e− overflowed from the first photodiode PD1 may move in the direction of the first surface FS and may move to the first floating diffusion region FD1 through the doped region DR.

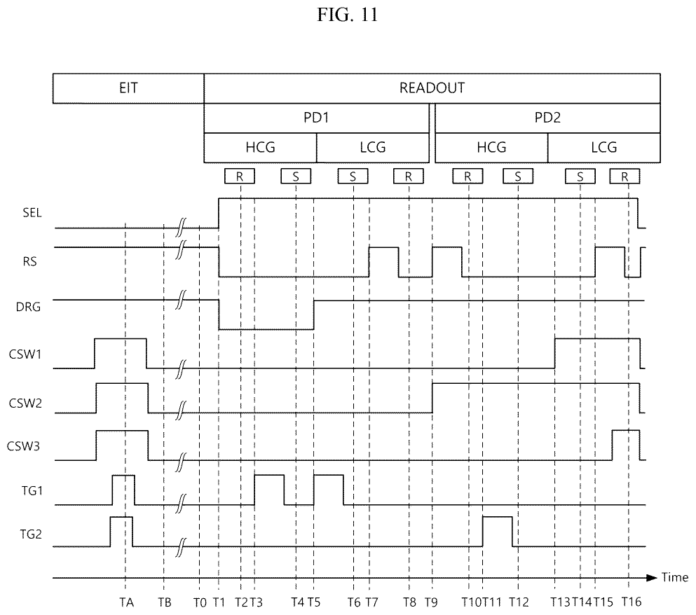

FIG. 11 is a diagram illustrating an example of the operation of a pixel PX, according to the embodiment of FIG. 2, according to an example embodiment. The pixel PX of FIG. 11 may include and/or may be similar in many respects to the pixels PX described above with reference to FIGS. 1 to 10, and may include additional features not mentioned above. The operation of the pixel PX is described with reference to FIGS. 2 and 11.

Referring to FIG. 11, the pixel PX is reset at time TA, and may be exposed to light during a period including time TB.

At time T0, the reset control signal RS and the gain control signal DRG provided to the pixel PX may be at a high level, and the reset transistor RX and the gain control transistor DRX may be turned on. The reset voltage of the power supply voltage node VDD may be provided to the first node N1, the third floating diffusion region FD3, and the first floating diffusion region FD1. The third floating diffusion region FD3 and the first floating diffusion region FD1 may be reset by the reset voltage provided by the power supply voltage node VDD.

At time T1, the reset transistor RX and the gain control transistor DRX may be turned off. The third floating diffusion region FD3 may be electrically separated from the first floating diffusion region FD1.

At time T2, a reset signal corresponding to the voltage of the first floating diffusion region FD1 may be output from the pixel PX. The reset signal may be and/or may include a reset signal based on the high conversion gain HCG of the first photodiode PD1.

At time T3, the first transfer transistor TX1 may be turned on by the first transfer signal TG1, and the photocharges of the first photodiode PD1 may move to the first floating diffusion region FD1.

At time T4, a pixel signal corresponding to the voltage of the first floating diffusion region FD1 to which the photocharges have moved may be output from the pixel PX. The pixel signal may be and/or may include a pixel signal based on the high conversion gain HCG of the first photodiode PD1.

At time T5, the gain control transistor DRX may be turned on by the gain control signal DRG. The third floating diffusion region FD3 may be electrically coupled to the first floating diffusion region FD1.

At time T6, a pixel signal corresponding to the voltage of the first floating diffusion region FD1 to which the third floating diffusion region FD3 is electrically coupled may be output from the pixel PX. The pixel signal may be and/or may include a pixel signal based on the low conversion gain LCG of the first photodiode PD1.

At time T7, the reset transistor RX may be turned on by the reset control signal RS, and the third floating diffusion region FD3 and the first floating diffusion region FD1 may be reset by the reset voltage provided by the power supply voltage node VDD.

At time T8, a reset signal corresponding to the voltage of the first floating diffusion region FD1 to which the third floating diffusion region FD3 is electrically coupled may be output from the pixel PX. The reset signal may be and/or may include a reset signal based on the low conversion gain LCG of the first photodiode PD1.

At time T9, the second transistor TSW2 may be turned on by the second control signal CSW2. Alternatively or additionally, the reset transistor RX may be turned on by the reset control signal RS. The gain control transistor DRX may be turned on. Accordingly, the first floating diffusion region FD1, the second floating diffusion region FD2, and the third floating diffusion region FD3 may be reset by the reset voltage provided by the power supply voltage node VDD.

At time T10, a reset signal corresponding to the voltage of the first floating diffusion region FD1 electrically coupled to the second floating diffusion region FD2 and the third floating diffusion region FD3 may be output from the pixel PX. The reset signal may be and/or may include a reset signal based on the high conversion gain HCG of the second photodiode PD2.

At time T11, the second transfer transistor TX2 may be turned on by the second transfer signal TG2, and the photocharges of the second photodiode PD2 may move to the second floating diffusion region FD2.

At time T12, a pixel signal corresponding to the voltage of the first floating diffusion region FD1 electrically coupled to the second floating diffusion region FD2 and the third floating diffusion region FD3 may be output from the pixel PX. The pixel signal may be and/or may include a pixel signal based on the high conversion gain HCG of the second photodiode PD2.

At time T13, the first transistor TSW1 connecting the second floating diffusion region FD2 and the overflow capacitor CLOFIC may be turned on by the first control signal CSW1. The capacitance of the overflow capacitor CLOFIC may be provided to the first floating diffusion region FD1 electrically coupled to the second floating diffusion region FD2 and the third floating diffusion region FD3.

At time T14, a pixel signal corresponding to the voltage of the first floating diffusion region FD1 electrically coupled to the overflow capacitor CLOFIC, the second floating diffusion region FD2, and the third floating diffusion region FD3 may be output from the pixel PX. The pixel signal may be and/or may include a pixel signal based on the low conversion gain LCG of the second photodiode PD2.

At time T15, the reset transistor RX may be turned on by the reset control signal RS, and the overflow capacitor CLOFIC, the second floating diffusion region FD2, the third floating diffusion region FD3, and the first floating diffusion region FD1 may be reset.

At time T16, a reset signal corresponding to the voltage of the first floating diffusion region FD1 electrically coupled to the overflow capacitor CLOFIC, the second floating diffusion region FD2, and the third floating diffusion region FD3 may be output from the pixel PX while the third transistor TSW3 is turned on. The reset signal may be and/or may include a reset signal based on the low conversion gain LCG of the second photodiode PD2.

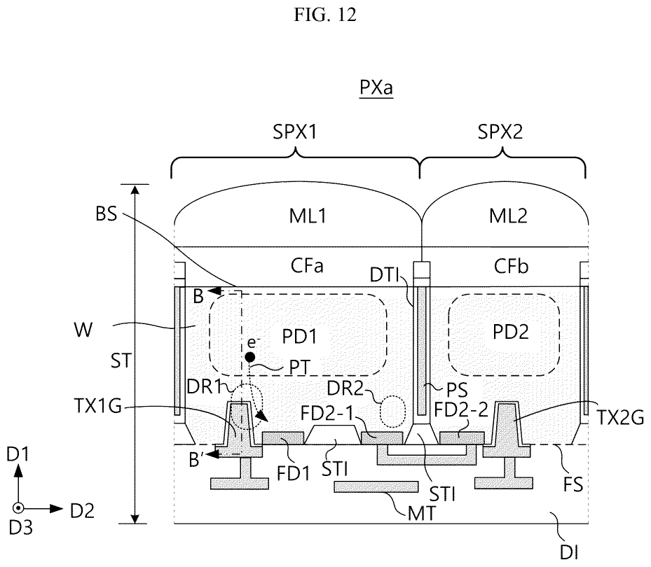

FIG. 12 is a diagram illustrating an example of a cross-section taken along line A-A′ of the layout of the pixel in FIG. 7. The cross-section of a pixel PX depicted in FIG. 12 is similar in many respects to the cross-sections of the pixel PX described above with reference to FIG. 9, and may include additional features not mentioned above. Furthermore, the pixel PXa of FIG. 12 may include and/or may be similar in many respects to the pixel PX described above with reference to FIGS. 1 to 11, and may include additional features not mentioned above. Consequently, repeated descriptions of the cross-section of the pixel PX of FIG. 12 described above with reference to FIGS. 1 to 11 may be omitted for the sake of brevity.

The pixel PXa, according to an example embodiment, may include a BDTI structure as a DTI structure. A first subpixel SPX1 of the pixel PXa may include a first doped region DR1 doped with N-type dopants. The first doped region DR1 may be disposed farther from a first surface FS than a first floating diffusion region FD1. The first doped region DR1 may be disposed closer to the first surface FS than the first photodiode PD1. The first doped region DR1 may be disposed at a predetermined distance from each of the first photodiode PD1 and the first floating diffusion region FD1. The first doped region DR1 may be disposed between the first photodiode PD1 and the first floating diffusion region FD1. Photocharges e− overflowed from the first photodiode PD1 may move to the first floating diffusion region FD1 through the doped region DR along a virtual path PT. Accordingly, the photocharges e− overflowed from the first photodiode PD1 may not escape to the 2-1-th floating diffusion region FD2-1. As a result, blooming and signal loss of the first subpixel SPX1 may be prevented and/or reduced, when compared to related image sensors.

A cross-section taken along line B-B′ of the cross-section of the pixel PX in FIG. 12 may be similar in many respects to the cross-section described with reference to FIG. 10.

In an example embodiment, the pixel PXa may include a second doped region DR2 doped with P-type dopants. The second doped region DR2 may be disposed between the first photodiode PD1 and the 2-1-th floating diffusion region FD2-1. The second doped region DR2 may prevent charges, overflowed from the first photodiode PD1, from escaping and moving to the 2-1-th floating diffusion region FD2-1 or from moving to the second subpixel SPX2 through the BDTI structure. As a result, blooming may be prevented and/or reduced, when compared to related image sensors.

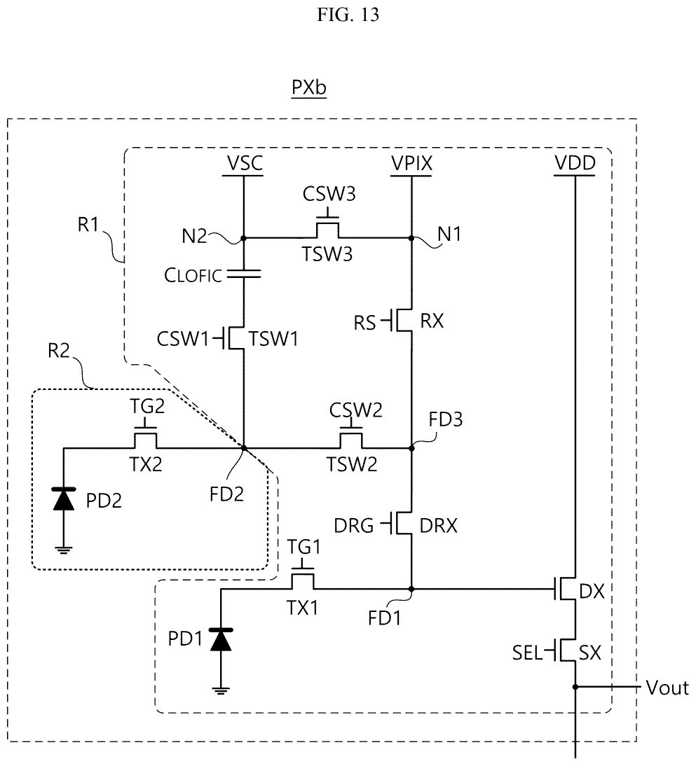

FIG. 13 is a diagram illustrating an example of the layout of the pixel based on the circuit diagram of FIG. 2, according to an example embodiment. A circuit diagram of a pixel PXb in FIG. 13 is similar in many respects to the circuit diagrams of the pixel PX described above with reference to FIGS. 2 and 6, and may include additional features not mentioned above. Consequently, repeated descriptions of the circuit diagram of FIG. 13 described above with reference to FIGS. 2 and 6 may be omitted for the sake of brevity.

Referring to FIG. 13, the pixel PXb, according to an example embodiment, may include a second photodiode PD2 disposed in a second region R2, and a second transfer transistor TX2. The first transistor TSW1 may be disposed in a first region R1. A second floating diffusion region FD2 of the pixel PXb may be divided and disposed in both the first region R1 and the second region R2, similarly to the pixel PX described with reference to FIG. 9. For example, the second floating diffusion region FD2 may be divided into a 2-1-th floating diffusion region and a 2-2-th floating diffusion region that are electrically connected to each other. The 2-1-th floating diffusion region may be disposed in the first region R1, and the 2-2-th floating diffusion region may be disposed in the second region R2.

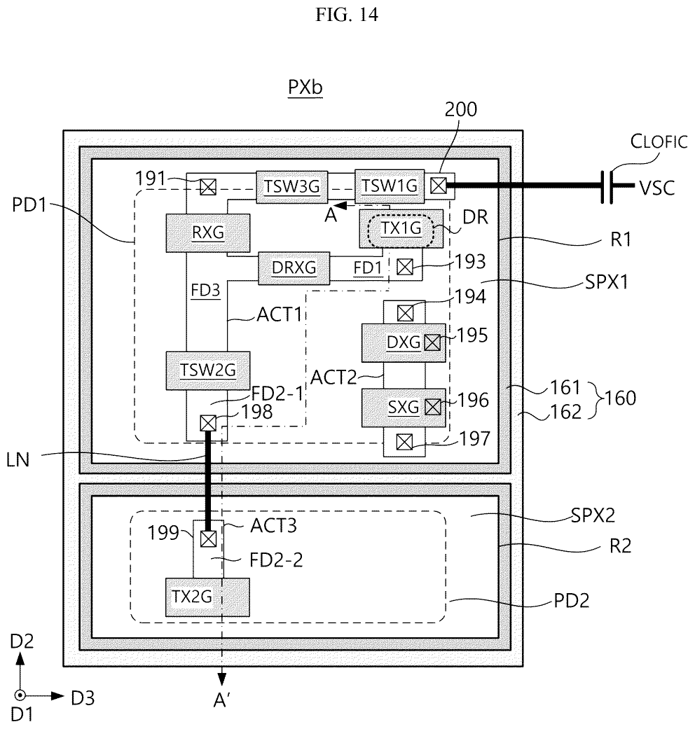

FIG. 14 is a plan view illustrating a schematic example of a layout of the pixel PXb of FIG. 13, according to an example embodiment. The plan view may be a plan view when viewed from a first direction D1 perpendicular to the substrate. The layout of the pixel PXb in FIG. 14 is similar in many respects to the layout of the pixel PX described above with reference to FIG. 7, and may include additional features not mentioned above. Consequently, repeated descriptions of the layout of FIG. 14 described above with reference to FIG. 7 may be omitted for the sake of brevity.

Referring to FIG. 14, the pixel PXb, according to an example embodiment, may include a second photodiode PD2 disposed in a second region R2, and a second transfer transistor TX2. A first transistor TSW1 may be disposed in a first region R1. A first subpixel SPX1 disposed in the first region may include a gate terminal TSW1G of the first transistor TSW1. One end of an overflow capacitor CLOFIC may be connected to the tenth contact 200 disposed in the first subpixel SPX1. A second floating diffusion region FD2 may be divided into a 2-1-th floating diffusion region FD2-1 and a 2-2-th floating diffusion region FD2-2 that are electrically connected to each other. The 2-1-th floating diffusion region FD2-1 may be disposed in the first region R1, and the 2-2-th floating diffusion region FD2-2 may be disposed in the second region R2.

A cross-section taken along line A-A′ of the layout of the pixel PXb in FIG. 14 may be similar in many respects to the cross-section of pixel PX described above with reference to FIG. 9.

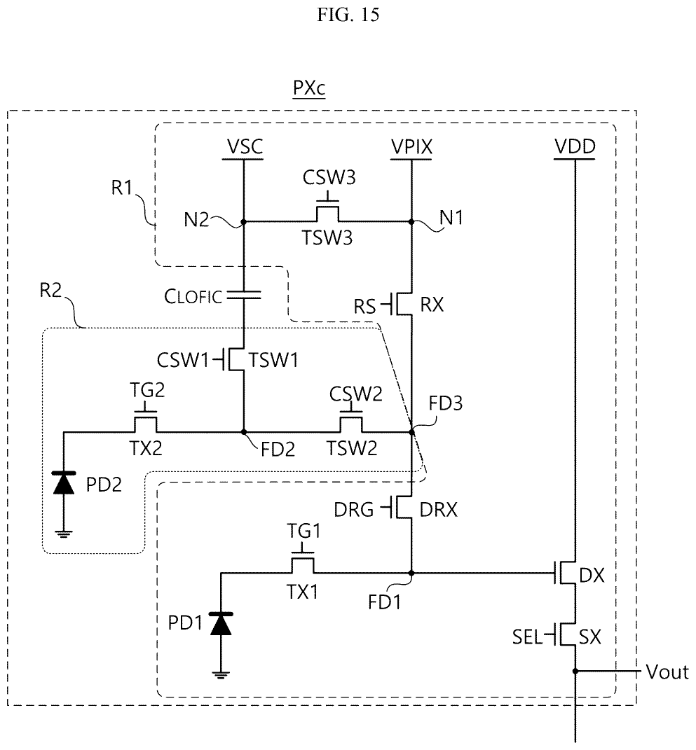

FIG. 15 is a diagram illustrating an example of the layout of the pixel based on the circuit diagram of FIG. 2, according to an example embodiment. A circuit diagram of a pixel PXc in FIG. 15 may be similar in many respects to the circuit diagram of the pixel PX described above with reference to FIGS. 2 and 6 and the circuit diagram of the pixel PXb described above with reference to FIG. 13, and may include additional features not mentioned above. Consequently, repeated descriptions of the circuit diagram of FIG. 15 described above with reference to FIGS. 2, 6, and 13 may be omitted for the sake of brevity.

Referring to FIG. 15, the pixel PXc, according to an example embodiment, may have a third floating diffusion region FD3 that may be divided and disposed in both the first region R1 and the second region R2, rather than a second floating diffusion region FD2. For example, the third floating diffusion region FD3 may be divided into a 3-1-th floating diffusion region and a 3-2-th floating diffusion region that may be electrically connected to each other. The 3-1-th floating diffusion region may be disposed in the first region R1, and the 3-2-th floating diffusion region may be disposed in the second region R2.

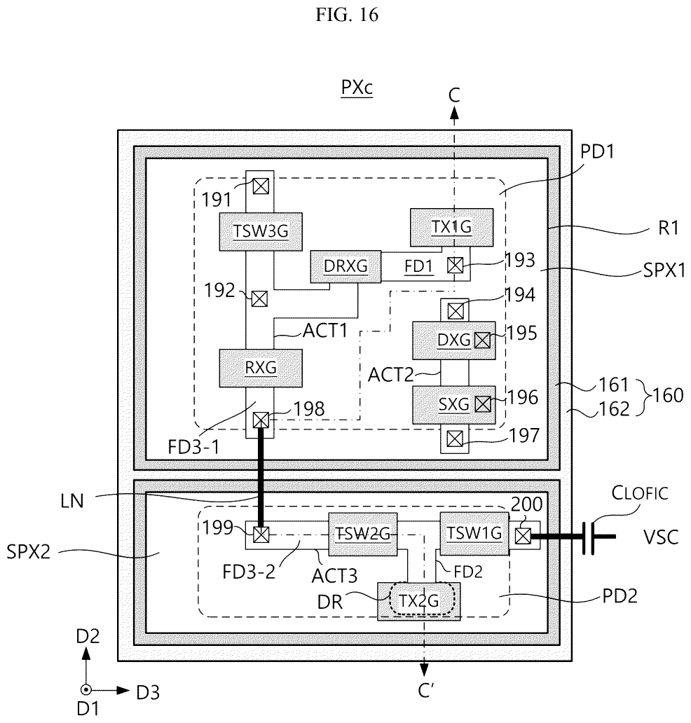

FIG. 16 is a plan view of a schematic example of a layout of the pixel PXc of FIG. 15. The plan view may be a plan view when viewed from a first direction D1 perpendicular to the substrate. The layout of the pixel PXc in FIG. 16 is similar in many respects to the layout of the pixel PX described above with reference to FIG. 7 and the layout of the pixel PXb described above with reference to FIG. 14, and may include additional features not mentioned above. Consequently, repeated descriptions of the layout of FIG. 16 described above with reference to FIGS. 7 and 14 may be omitted for the sake of brevity.

Referring to FIG. 16, a pixel PXc, according to an example embodiment, may include a second photodiode PD2, a second transfer transistor TX2, a first transistor TSW1, and a second transistor TSW2 disposed in a second region R2. According to example embodiments, a third transistor TSW3 may be disposed in a first region R1 or the second region R2. A third floating diffusion region FD3 may be divided into a 3-1-th floating diffusion region FD3-1 and a 3-2-th floating diffusion region FD3-2 that are electrically connected to each other. The 3-1-th floating diffusion region FD3-1 and the 3-2-th floating diffusion region FD3-2 may be connected by an interconnection LN between the ninth contact 199 and the tenth contact 200 and may have the same potential. The 3-1-th floating diffusion region FD3-1 may be disposed in the first region R1, and the 3-2-th floating diffusion region FD3-2 may be disposed in the second region R2.

Referring to FIG. 16, in an example embodiment, a first subpixel SPX1 may be disposed in the first region R1, and a second subpixel SPX2 may be disposed in the second region R2. The first subpixel SPX1 disposed in the first region may include a first photodiode PD1, a gate terminal TX1G of a first transfer transistor, a gate terminal DXG of a driving transistor, a gate terminal SXG of a select transistor, a gate terminal RXG of a reset transistor, a gate terminal TSW3G of a third transistor, and a first floating diffusion region FD1. The second subpixel SPX2 disposed in the second region may include a second photodiode PD2, a gate terminal TX2G of a second transfer transistor, a doped region DR, a gate terminal TSW1G of a first transistor, and a gate terminal TSW2G of a second transistor.

In an example embodiment, the first contact 191 may be connected to a voltage node VSC and one end of the overflow capacitor CLOFIC of FIG. 15, and the second contact 192 may be connected to a pixel voltage node VPIX. The third contact 193 may be connected to the fifth contact 195. The fourth contact 194 may be connected to a power supply voltage node VDD, the sixth contact 196 may receive a select signal SEL, and the seventh contact 197 may be connected to a column line. The eighth contact 198 may be connected to the ninth contact 199, and the tenth contact 200 may be connected to the other end of the overflow capacitor CLOFIC.

According to an example embodiment, a third floating diffusion region FD3 of the pixel PX may be divided into a plurality of regions. The third floating diffusion region FD3 divided into a plurality of regions may be disposed in both the first region R1 and the second region R2. For example, the third floating diffusion region FD3 may be divided into a 3-1-th floating diffusion region FD3-1 and a 3-2-th floating diffusion region FD3-2. The 3-1-th floating diffusion region FD3-1 and the 3-2-th floating diffusion region FD3-2 may be electrically connected to each other through an interconnection LN and may have the same potential.

The first region R1 and the second region R2 may be separated by a separation structure 160. In an example embodiment, the separation structure 160 may be and/or may include a DTI structure, and may include a conductive layer 161 and a separation insulating layer 162.

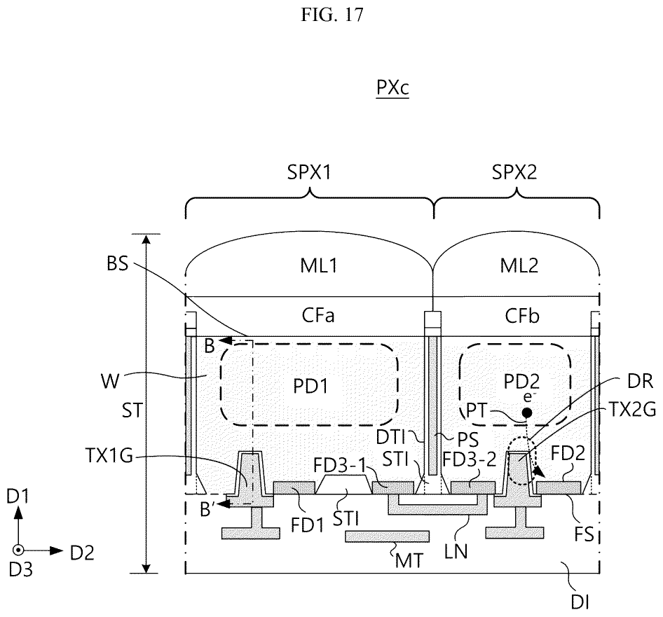

FIG. 17 is a diagram illustrating an example of a cross-section taken along line C-C′ of the layout of the pixel PXc in FIG. 16. Descriptions similar to or overlapping with those provided with reference to FIG. 9 are omitted for brevity. A pixel of FIG. 17 may correspond to the pixel PX of FIGS. 1 to 8. The cross-section of the pixel PXc in FIG. 17 is similar in many respects to the cross-section of the pixel PX described above with reference to FIG. 9 and the cross-section of the pixel PXa described above with reference to FIG. 12, and may include additional features not mentioned above. Furthermore, the pixel PXc of FIG. 17 may include and/or may be similar in many respects to the pixels PX, PXa, and PXb described above with reference to FIGS. 1 to 14, and may include additional features not mentioned above. Consequently, repeated descriptions of the cross-section of the pixel PXc of FIG. 17 described above with reference to FIGS. 1 to 14 may be omitted for the sake of brevity.

Referring to FIG. 17, the second subpixel SPX2 of the pixel PXc, according to an example embodiment, may include a doped region DR doped with N-type dopants. The doped region DR may be disposed farther from the first surface FS than the second floating diffusion region FD2. The doped region DR may be disposed closer to the first surface FS than the second photodiode PD2. The doped region DR may be disposed at a predetermined distance from each of the second photodiode PD2 and the second floating diffusion region FD2. The doped region DR may be disposed between the second photodiode PD2 and the second floating diffusion region FD2. Photocharges e− overflowed from the second photodiode PD2 may move to the second floating diffusion region FD2 through the doped region DR along a virtual path PT. Accordingly, the photocharges e− overflowed from the second photodiode PD2 may not escape to the 3-2-th floating diffusion region FD3-2. As a result, blooming and signal loss of the second subpixel SPX2 may be prevented and/or reduced, when compared to related image sensors.

In an example embodiment, a separation structure DTI of the pixel PXc may be and/or may include a BDTI structure. The separation structure DTI may optionally include a doped region doped with P-type dopants. The doped region doped with P-type dopants may be disposed between the second photodiode PD2 and the 3-2-th floating diffusion region FD3-2. The doped region doped with P-type dopants may prevent and/or reduce charges, overflowed from the second photodiode PD2, from moving to the 3-2-th floating diffusion region FD3-2 or from moving to the first subpixel SPX1 through the BDTI structure. As a result, blooming may be prevented and/or reduced, when compared to related image sensors.

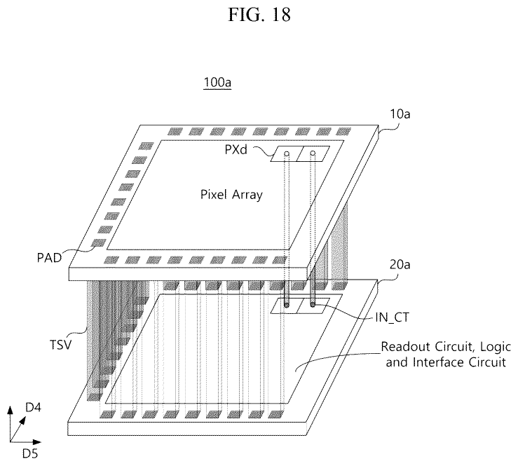

FIG. 18 is a block diagram of an image sensor 100a, according to an example embodiment. The image sensor 100a may include and/or may be similar in many respects to the image sensor 100 described above with reference to FIG. 1 and may include additional features not mentioned above. Consequently, repeated descriptions of the image sensor 100a described above with reference to FIG. 1 may be omitted for the sake of brevity.

The image sensor 100a may include a first substrate 10a and second substrate 20a, which may be stacked.

For example, the first substrate 10a may be stacked on the second substrate 20a in a direction D1, which is perpendicular to a plane of the substrate (e.g., a plane parallel to D4 and D5). The first substrate 10a and the second substrate 20a may be electrically connected to each other. For example, the first substrate 10a and the second substrate 20a may transmit a pixel signal and/or a control signal through a through-silicon via (TSV) disposed in a peripheral region of the substrate. The first substrate 10a and the second substrate 20a may also be electrically connected to each other through an in-pixel contact within the pixel PXd. The in-pixel contact may be, for example, a Cu-to-Cu (C2C) bonding contact. However, the present disclosure is not limited in this regard. The pixel signal of the first substrate 10a may be transmitted to a readout circuit (or an image signal processing logic) of the second substrate 20a.

The second substrate 20a may include at least one of a readout circuit, a timing controller, image signal processing logic, or an interface circuit.

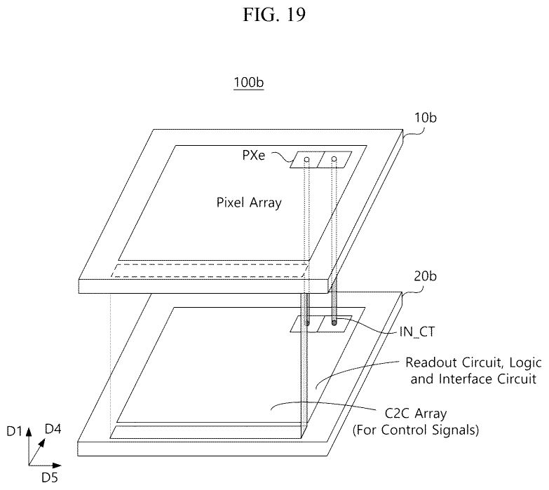

FIG. 19 is a diagram illustrating an image sensor 100b, according to an example embodiment. The image sensor 100b may include and/or may be similar in many respects to the image sensors 100 and 100a described above with reference to FIGS. 1 and 18, respectively, and may include additional features not mentioned above. Consequently, repeated descriptions of the image sensor 100b described above with reference to FIGS. 1 and 18 may be omitted for the sake of brevity.

The image sensor 100b may include a first substrate 10b and second substrate 20b, which may be stacked. The first substrate 10a and the second substrate 20a may be connected to each other through a wafer bonding process using a pixel-level C2C interconnections. The first substrate 10a and the second substrate 20a may be electrically connected to each other not only through an in-pixel contact within a pixel PXe but also through a C2C array disposed in a peripheral region of the substrate. Control signals for controlling a pixel circuit may be transmitted through the C2C array. A pixel signal of the first substrate 10b may be transmitted to a readout circuit (or an image signal processing logic) of the second substrate 20b.

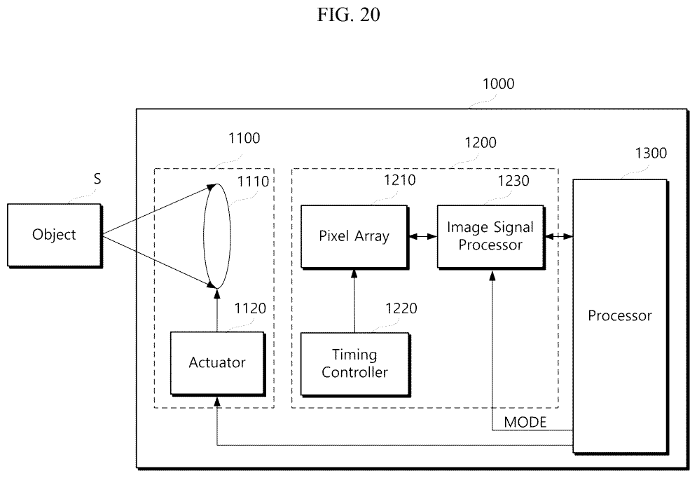

FIG. 20 is a diagram illustrating an electronic device 1000, according to an example embodiment. The electronic device 1000 may include and/or may be similar in many respects to the image sensors 100, 100a, and 100b described above with reference to FIGS. 1, 18, and 19, respectively, and may include additional features not mentioned above. Consequently, repeated descriptions of the electronic device 1000 described above with reference to FIGS. 1, 18, and 19 may be omitted for the sake of brevity.

The electronic device 1000 may include an image-capturing unit 1100, an image sensor 1200, and a processor 1300.

In an example embodiment, the electronic device 1000 may perform autofocusing based on phase data provided from the image sensor 1200 to the processor 1300.

The processor 1300 may control the overall operation of the electronic device 1000. The processor 1300 may provide a control signal to the lens driving unit (actuator) 1120 to control a location of the lens 1110. As a result, a focal length may be controlled.

In an example embodiment, the processor 1300 may transmit a control signal MODE, requesting to generate an image in high dynamic range (HDR) mode to the image sensor 1200.

The image-capturing unit 1100 may be and/or may include a light-receiving component, and may include a lens 1110 and the actuator 1120. The lens 1110 may include a plurality of lenses.

The actuator 1120 may move the lens 1110 in a direction in which a distance from an object S increases and/or decreases based on a control signal of the processor 1300.

The image sensor 1200 may generate image data based on incident light. The image sensor 1200 may include a pixel array 1210, a timing controller 1220, an ADC 1230, and an image signal processor 1240.

Pixels of the pixel array 1210 may include at least one photoelectric conversion element. In an example embodiment, the pixels of the pixel array 1210 may include and/or may be similar in many respects to the pixels PX, PXa, PXb, and PXc described above with reference to FIGS. 1 to 17, and may include additional features not mentioned above.

According to an example embodiment, each of the pixels of the pixel array 1210 may include a plurality of subpixels. Each of the subpixels of each of the pixels may include a photodiode. The subpixels may be separated by a separation structure. The pixels may include a plurality of floating diffusion regions. One of the plurality of floating diffusion regions may be divided and disposed in each of the plurality of subpixels, and the divided floating diffusion regions may be electrically connected to each other and have the same potential. One of the subpixels may include a doped region doped with N-type dopants between a single photodiode and the floating diffusion region. The floating diffusion region adjacent to the doped region may not be a floating diffusion region that has been separated and disposed a plurality of subpixels.

According to various aspects of the present disclosure, an image sensor according to example embodiments may reduce and/or prevent blooming and/or image signal loss that may be caused by movement of photocharges through an unintended path.

While example embodiments have been shown and described above, it is to be apparent to those skilled in the art that modifications and variations may be made without departing from the scope of the present disclosure as defined by the appended claims.

What is claimed is:

1. An image sensor, comprising:
a plurality of pixels,
wherein each pixel of the plurality of pixels comprises:
a first photoelectric element;
a second photoelectric element different from the first photoelectric element;
a first transfer transistor coupling the first photoelectric element with a first floating diffusion region;
a second transfer transistor coupling the second photoelectric element with a second floating diffusion region;
a first transistor and a second transistor each coupling the first floating diffusion region and the second floating diffusion region with a third floating diffusion region, respectively;
a lateral overflow integration capacitor (LOFIC) coupled with the second floating diffusion region by a third transistor and configured to accumulate charges overflowed from the second photoelectric element;
a reset transistor coupling the third floating diffusion region with a power supply voltage;
a driving transistor having a gate coupled with the first floating diffusion region and configured to operate based on a voltage of the first floating diffusion region;
a select transistor having a first terminal coupled with the driving transistor and a second terminal coupled with a column line;
a deep trench isolation (DTI) structure between the first photoelectric element and the second photoelectric element; and
a first doped region doped with N type dopants and disposed between at least one of the first photoelectric element and the first floating diffusion region or the second photoelectric element and the second floating diffusion region.

2. The image sensor of claim 1, wherein the first photoelectric element comprises a first light-receiving area,
wherein the second photoelectric element comprises a second light-receiving area, and
wherein the first light-receiving area is larger than the second light-receiving area.

3. The image sensor of claim 1, wherein the DTI structure is formed as at least one of a front-side deep trench isolation (FDTI) or a back-side deep trench isolation (BDTI) structure.

4. The image sensor of claim 1, wherein the first doped region is doped with N-type (N minus) dopants.

5. The image sensor of claim 1, wherein the first doped region is disposed at a predetermined depth to be separated in a direction perpendicular to a plane of a substrate from the at least one of the first photoelectric element and the first floating diffusion region or the second photoelectric element and the second floating diffusion region.

6. The image sensor of claim 5, wherein the first doped region is disposed between the first photoelectric element and the first floating diffusion region,
wherein the first transfer transistor comprises a vertical gate, and
wherein at least a portion of the first doped region overlaps the vertical gate of the first transfer transistor when viewed from the direction perpendicular to the plane of the substrate.

7. The image sensor of claim 6, wherein the first doped region does not overlap the first floating diffusion region when viewed from the direction perpendicular to the plane of the substrate.

8. The image sensor of claim 6, wherein the second floating diffusion region comprises a 2-1-th floating diffusion region and a 2-2-th floating diffusion region with the DTI structure interposed therebetween, and
wherein the image sensor further comprises a first interconnection electrically coupling the 2-1-th floating diffusion region with the 2-2-th floating diffusion region.

9. The image sensor of claim 8, further comprising:
a second doped region doped with P-type dopants and disposed between the first photoelectric element and the 2-1-th floating diffusion region.

10. The image sensor of claim 5, wherein the first doped region is disposed between the second photoelectric element and the second floating diffusion region,
wherein the second transfer transistor comprises a vertical gate, and
wherein the first doped region comprises a center disposed between the vertical gate of the second transfer transistor and the second floating diffusion region.

11. The image sensor of claim 10, wherein the first doped region does not overlap the second floating diffusion region.

12. The image sensor of claim 10, wherein the third floating diffusion region comprises a 3-1-th floating diffusion region and a 3-2-th floating diffusion region with the DTI structure interposed therebetween, and
wherein the image sensor further comprises a second interconnection electrically coupling the 3-1-th floating diffusion region with the 3-2-th floating diffusion region.

13. The image sensor of claim 12, further comprising:
a second doped region doped with P-type dopants and disposed between the second photoelectric element and the 3-1-th floating diffusion region.

14. The image sensor of claim 1, wherein the first doped region is configured to provide at least one of:
a first path configured to move first photocharges overflowed from the first photoelectric element to the first floating diffusion region; or
a second path configured to move second photocharges overflowed from the second photoelectric element to the second floating diffusion region.

15. The image sensor of claim 1, further comprising:
a shallow trench isolation (STI) structure coupled with the DTI structure.

16. The image sensor of claim 1, wherein the DTI structure comprises a back-side deep trench isolation (BDTI) structure, and
wherein the image sensor further comprises a third doped region doped with P-type dopants and disposed between at least one of the first photoelectric element and the second floating diffusion region or the second photoelectric element and the third floating diffusion region.

17. An image sensor, comprising:
a pixel array comprising a plurality of pixels; and
a readout circuit configured to receive a pixel signal from each pixel of the plurality of pixels,
wherein each pixel of the plurality of pixels comprises:
a plurality of subpixels separated from each other by a deep trench isolation (DTI) structure;
a plurality of floating diffusion regions; and
a lateral overflow integration capacitor (LOFIC) configured to accumulate overflowed charges,
wherein each subpixel of the plurality of subpixels comprises a photoelectric element,
wherein a divided floating diffusion region of the plurality of floating diffusion regions is divided into a plurality of floating diffusion sub-regions disposed in respective subpixels of the plurality of subpixels, and the plurality of floating diffusion sub-regions have a same potential,
wherein a first subpixel of the plurality of subpixels comprises a doped region doped with N type dopants and is disposed between another floating diffusion region of the plurality of floating diffusion regions and the photoelectric element, and
wherein the another floating diffusion region is not divided.

18. The image sensor of claim 17, wherein each subpixel of the plurality of subpixels comprises a first photoelectric element and a second photoelectric element different from the first photoelectric element,
wherein the plurality of floating diffusion regions comprises:
a first floating diffusion region coupled with the first photoelectric element and a first transfer transistor;
a second floating diffusion region coupled with the second photoelectric element and a second transfer transistor; and
a third floating diffusion region coupled with the first floating diffusion region through the first transfer transistor, and coupled with the second floating diffusion region through the second transfer transistor, and
wherein the divided floating diffusion region comprises at least one of the second floating diffusion region and the third floating diffusion region.

19. The image sensor of claim 18, wherein each pixel of the plurality of pixels comprises a first region and a second region separated by the DTI structure,
wherein the first photoelectric element is disposed in the first region, and
wherein the second photoelectric element is disposed in the second region.

20. An image sensor, comprising:
a first photoelectric element having a first area and being disposed in a first region;
a second photoelectric element having a second area and being disposed in a second region, the second area being smaller than the first area;
a deep trench isolation (DTI) structure separating the first region and the second region;
a first transfer transistor coupling a first floating diffusion region with the first photoelectric element;
a second transfer transistor coupling a second floating diffusion region with the second photoelectric element;
a third floating diffusion region selectively electrically coupled to at least one of the first floating diffusion region or the second floating diffusion region; and
a lateral overflow integration capacitor (LOFIC) configured to accumulate charges overflowed from the second photoelectric element,
wherein at least one of the second floating diffusion region or the third floating diffusion region is divided into divided floating diffusion regions,
wherein the divided floating diffusion regions are disposed in the first region and the second region,
wherein the divided floating diffusion regions have a same potential, and
wherein a doped region is doped with N-type dopants and is disposed to be spaced apart from at least one of the first photoelectric element or the second photoelectric element, and is disposed in at least one of the first region or the second region.
